(19) United States
(12) Patent Application Publication
(10) Pub. No.: US 2016/0293579 A1
(43) Pub. Date: Oct. 6, 2016

(54) INTEGRATION STRUCTURES FOR HIGH CURRENT APPLICATIONS

(71) Applicant: GLOBALFOUNDRIES Inc., Grand Cayman (KY)

(72) Inventors: Luke ENGLAND, Saratoga Springs, NY (US); Sukeshwar KANNAN, Malta, NY (US); Daniel SMITH, Ballston Spa, NY (US)

(21) Appl. No.: 14/678,016

(22) Filed: Apr. 3, 2015

(51) Int. Cl. H01L 25/065; H01L 21/48; H01L 25/00; H01L 23/498

(52) U.S. Cl. CPC H01L 25/0657; H01L 23/498; H01L 23/49816; H01L 23/49827; H01L 23/49838; H01L 23/49866; H01L 21/4846; H01L 21/486; H01L 21/4853; H01L 25/50; H01L 2225/06517; H01L 2225/06541; H01L 2225/06548

(57) ABSTRACT

Through-silicon-vias (TSV) to back end of line (BEOL) integration structures and a method of manufacturing the same are disclosed. Embodiments include providing a bottom die of a three-dimensional (3D) integrated circuit (IC) stack, the bottom die having a connection pad; providing a top die of the 3D IC stack, the top die including a plurality of metallization layers having a plurality of intermetal vias provided between the plurality of metallization layers; forming a BEOL connection structure between the bottom and top dies, the BEOL connection structure having a plurality of power supply TSVs; and connecting the connection pad electrically to the intermetal vias through the power supply TSVs.

### TECHNICAL FIELD

The present disclosure relates to the manufacture of semiconductor devices, and, more specifically, to a process for providing a power delivery structure for connecting structures in upper metal layers. The present disclosure is particularly applicable to semiconductor devices for the 14 nanometer (nm) technology node and beyond.

### BACKGROUND

Semiconductor devices are used in a large number of electronic devices, such as computers, cell phones, and others. Semiconductor devices include integrated circuits that are formed on semiconductor wafers by depositing many types of thin films of material over the semiconductor wafers, and patterning the thin films of material to form an integrated circuit (IC). Vias are used in forming ICs and may extend vertically from a bottom side of an IC die to a metal interconnection layer(s) on the active top side of the IC die. Existing technology provides through-silicon-via (TSV) integration schemes for Metal 1 (“M1”) connections. However, existing TSV schemes do not provide sufficient margin of reliability when delivering power directly to a stacked (upper) die in a three-dimensional (3D) application. Moreover, with existing technology there is a risk of electromigration failures in the back-end-of-line (BEOL) routing due to the limitation of metal layer current carrying capacity. Specifically, current industry requirements for existing logic-on-logic device stack is 8 to 12 milliamps (mA) per power TSV structure for top die power/ground connections. However, existing connection at M1 cannot withstand more than 0.7 mA of current without sustaining an electromigration failure.

A need therefore exists for methodology enabling delivery of sufficient power directly to a stacked (upper) die in a 3D application with a TSV integration scheme and reduced risk of electromigration failures in BEOL for high power applications and the resulting devices.

### SUMMARY

An aspect of the present disclosure is a method of providing a high current device including TSV to BEOL integration structures that provide sufficient power directly to a stacked (upper) die without the risk of electromigration failures in the BEOL stack.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method of providing a bottom die of a 3D IC stack, the bottom die having a connection pad; providing a top die of the 3D IC stack, the top die including a plurality of metallization layers having a plurality of intermetal vias provided between the plurality of metallization layers; forming a BEOL connection structure between the bottom and top dies, the BEOL connection structure having a plurality of power supply TSVs; and connecting the connection pad electrically to the intermetal vias through the power supply TSVs.

Aspects of the present disclosure include filling the power supply TSVs with tungsten or copper. Other aspects include providing the power supply TSVs which extend through a silicon containing substrate. Additional aspects include providing a first set of lower metallization layers over a first TSV; providing a second set of lower metallization layers over a second TSV adjacent to the first TSV; and converging upper metallization layers of the first and second TSV such that the upper metallization layers are disposed over a portion of both the first and second TSVs, wherein the upper metallization layers are thicker than the lower metallization layers. Yet other aspects include providing a third set of lower metallization layers over a third TSV, wherein the upper metallization layers are shared between the first, second, and third TSVs. Further aspects include providing a fourth set of lower metallization layers over a fourth TSV, wherein the upper metallization layers are shared between the first, second, third, and fourth TSVs. Other aspects include electrical current being spread among the first, second, third, and fourth TSVs. Another aspect includes the connection pad including a backside under bump metallization and solder. Yet other aspects include providing an inter-layer dielectric (ILD) between each of the metallization layers. Additional aspects include the intermetal vias allowing for a direct current flow path; and a number of intermetal vias between each metallization layer is sufficient to pass current based on a minimum current layer. Another aspect includes a maximum current per TSV being determined by a number of intermetal vias present in an upper metallization layer.

Another aspect of the present disclosure is a device including: a bottom die of a 3D IC stack, the bottom die having a connection pad; a top die of the 3D IC stack, the top die having a plurality of metallization layers including a plurality of intermetal vias provided between the plurality of metallization layers; and a BEOL connection structure between the bottom and top dies, the BEOL connection structure having a plurality of power supply TSVs, wherein the connection pad is electrically connected to the intermetal vias through the power supply TSVs.

Aspects include the TSVs being filled with tungsten or copper. Yet other aspects include the TSVs extending through a silicon containing substrate. Further aspects include a first set of lower metallization layers provided over a first TSV; a second set of lower metallization layers provided over a second TSV adjacent to the first TSV, wherein upper metallization layers of the first and second TSV are converged such that the upper metallization layers are disposed over a portion of both the first and second TSVs. Other aspects include a third set of lower metallization layers are provided over a third TSV; and a fourth set of lower metallization layers are provided over a fourth TSV, wherein the upper metallization layers are converged and shared between the first, second, third and fourth TSVs.

Another aspect of the present disclosure is a method including providing a bottom die of a 3D IC stack, the bottom die having a connection pad, the connection pad including a backside under bump metallization and solder; providing a top die of the 3D IC stack, the top die including a plurality of metallization layers having a plurality of intermetal vias provided between the plurality of metallization layers; forming a BEOL connection structure between the bottom and top dies, the BEOL connection structure having a plurality of power supply TSVs filled with copper or tungsten; providing a first set of lower metallization layers over a first TSV; providing a second set of lower metallization layers over a second TSV adjacent to the first TSV; converging upper metallization layers of the first and second TSV such that the upper metallization layers are disposed over a portion of both the first and second TSV; and connecting the connection pad electrically to the intermetal vias through the power supply TSVs.

Aspects of the present disclosure include providing an ILD between each of the metallization layers. Other aspects include providing a third set of lower metallization layers over a third TSV, wherein the upper metallization layers are converged and shared between the first, second and third TSVs. Yet other aspects include providing a fourth set of lower metallization layers over a fourth TSV, wherein the upper metallization layers are converged and shared between the first, second, third and fourth TSVs.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIGS. 1A and 1B schematically illustrate top and cross sectional views, respectively, of a single TSV layout and BEOL stack unit cell, in accordance with an exemplary embodiment;

FIGS. 2A and 2B schematically illustrate top and cross sectional views, respectively, of a double TSV layout and BEOL stack unit cell, in accordance with an exemplary embodiment;

FIGS. 3A and 3B schematically illustrate top and cross sectional views, respectively, of a double TSV layout and BEOL stack unit cell, in accordance with another exemplary embodiment;

FIGS. 4A and 4B schematically illustrate single and double TSV layouts in cross sectional views, respectively, in accordance with an exemplary embodiment;

FIGS. 5A and 5B schematically illustrate top and bottom views, respectively, of a triple TSV layout, in accordance with an exemplary embodiment; and

FIGS. 6A and 6B schematically illustrate top and bottom views, respectively, of a quadruple TSV layout, in accordance with an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problems of insufficient power delivery to a stacked die in a 3D application, as well as electromigration failures in BEOL routing, due to the limitation of metal layer current carrying capacity, by using TSV to BEOL integration structures for high current devices. A more streamlined power delivery path to the top die is provided with improved performance. In addition to power interconnects, a similar structure could be used for some input/output (I/O) circuits to reduce resistive capacitive (RC) delay and electromagnetic interference (EMI) effects. The use of high power TSV structures described herein allows for up to 12.8 mA of current, which satisfies the industry requirements.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

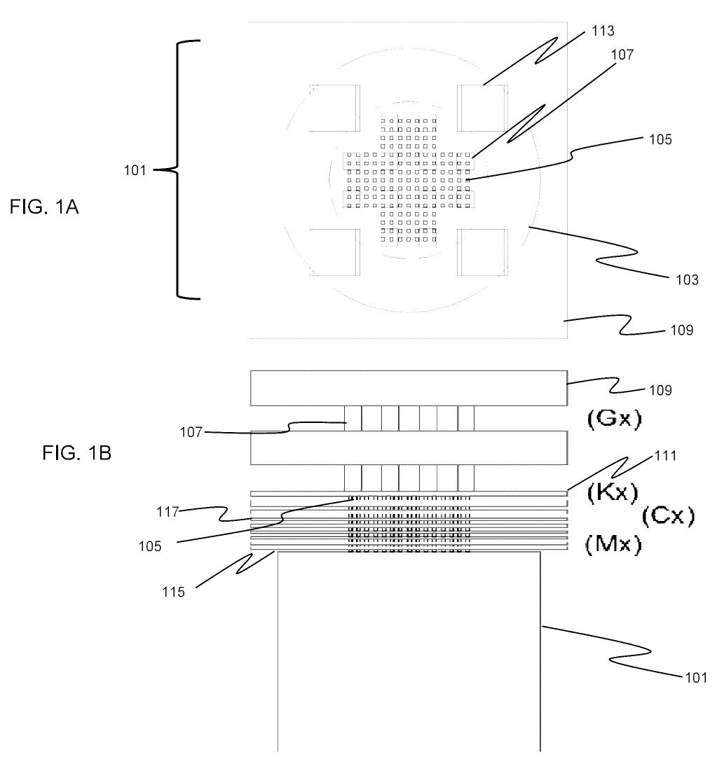

Attention is directed to FIGS. 1A and 1B, wherein top (overhead) and cross sectional views, respectively, of a single TSV contact layout are illustrated. The outer boundaries of a single power supply TSV 101 are indicated by the circle 103. Individual intermetal vias 105 adjacent metallization level Kx 111, and intermetal vias 107 adjacent metallization level Gx 109 are provided. Intermetal vias are also present between layers of the Mx 115 and Cx 117 levels. In this example, there are approximately 161 vias 105 in between two adjacent metallization layers of the Kx 111 level, which are each able to conduct 0.074 mA of current from a controlled-collapse chip connection (C4) or copper pillar (CuP) connection at 100° C. for a total of 12 mA. There are approximately 12 vias 107 adjacent the Gx level each able to conduct 0.33 mA of current from a C4 or CuP connection at 100° C. for a total of 12 mA. The blocks 113 represent inter-layer dielectric (ILD). The intermetal vias 105, 107 are stacked through the Mx levels 115 to Gx levels 109 for a continuous current flow path. BEOL routing connections are only permitted in the Gx level 109. The BEOL layer designs for the unit cell stack fall within conventional design rules. There is no TSV redundancy for this example. The maximum current per TSV is dictated by the number of vias in the Gx level, and the device provides a standard high current (e.g., 6 mA).

As an example, a TSV unit cell for 3 μm and 5 μm diameter variants can include a 32×32 nm size with 68 nm spacing, which would include 429 total vias (439,296 nm²). As another example, a TSV unit cell for 3 μm and 5 μm diameter variants can include a 64×64 nm size with 96 nm spacing, which would include 161 total vias (659,456 nm²). In another example, a TSV unit cell for 3 μm and 5 μm diameter variants can include a 32×64 nm size with 88 nm spacing, which would include 237 total vias (485,376 nm²).

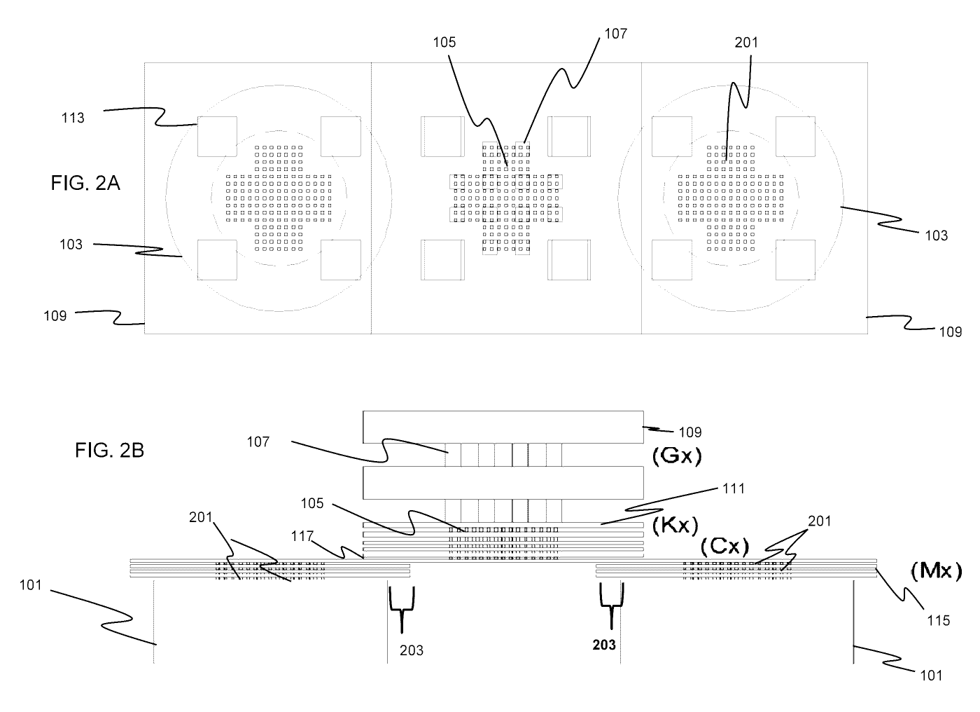

Attention is directed to FIGS. 2A and 2B, wherein top (overhead) and cross sectional views, respectively, of a double TSV contact layout are illustrated. The outer boundaries of two power supply TSVs 101 are indicated by the circles 103. Individual intermetal vias 105 between adjacent metallization layers of the Kx level 111, and intermetal vias 107 between adjacent metallization layers of the Gx 109 level are provided. Intermetal vias 201 are provided between metal layers of each of the Mx 115 and Cx 117 levels. In this example, the two TSVs 101 are separated at the Mx level 115 and merged at the first metal layer of the Cx level 117.

In FIG. 2B, an overlap 203 of the layers of the Mx level exists adjacent, but at a level above each TSV 101. Power is spread equally in order to minimize electron migration and current stress is mitigated by spreading the power load across the layers of the Mx/Vx levels. By creating the merger at this metallization level enhanced high current capability is generated (e.g., 6 mA). The converged BEOL stack in this example is not widened and therefore provides a minimal footprint and allows for increased routing space in the upper metallization levels.

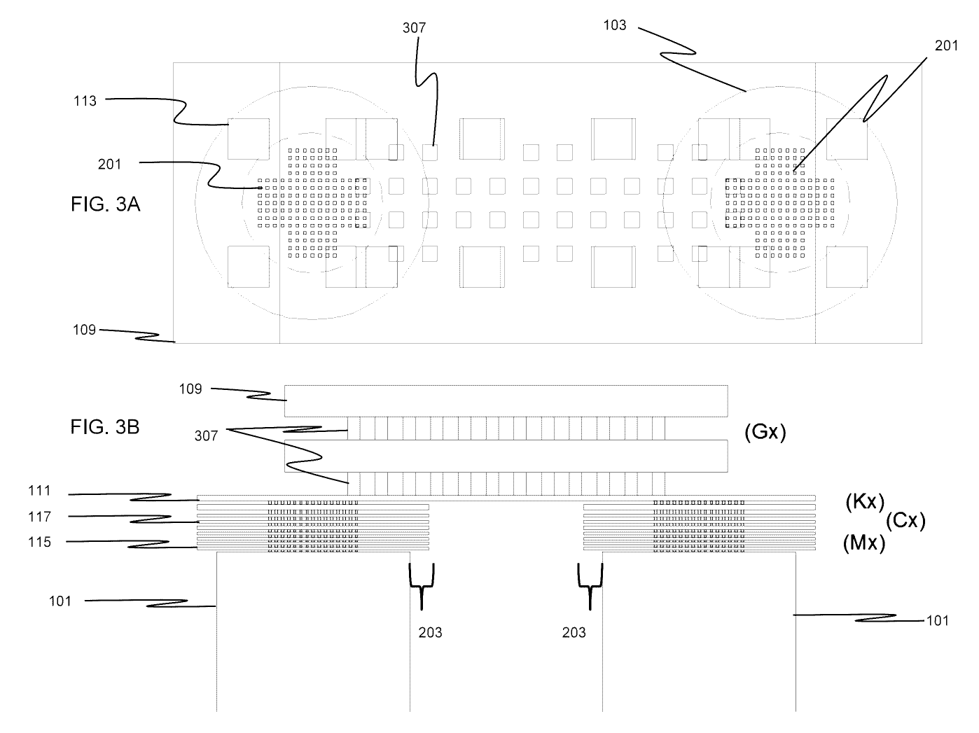

FIGS. 3A and 3B schematically illustrate top (overhead) and cross sectional views, respectively, of another example of a double TSV contact layout. In this example, the two TSVs 101 are separated at the Mx and Cx levels 115, 117 and merged at the top metal layer of the Kx level 111, at the final low-k dielectric layer (not shown). By creating the merger at this ultra-thick metallization layer, maximum current capability (e.g., 8 to 12 mA) is provided by widening the Gx pad and increasing the number of Kx to Gx transition vias 307. An overlap 203 of the layers of the Mx, Cx and Kx levels exists adjacent, but at a level above each TSV 101. Power is spread equally in order to minimize electron migration, and current stress is mitigated by spreading the power load across the layers of the Mx/Vx levels. A maximum current per TSV is dictated by the number of vias in a Cx-Kx transition layer.

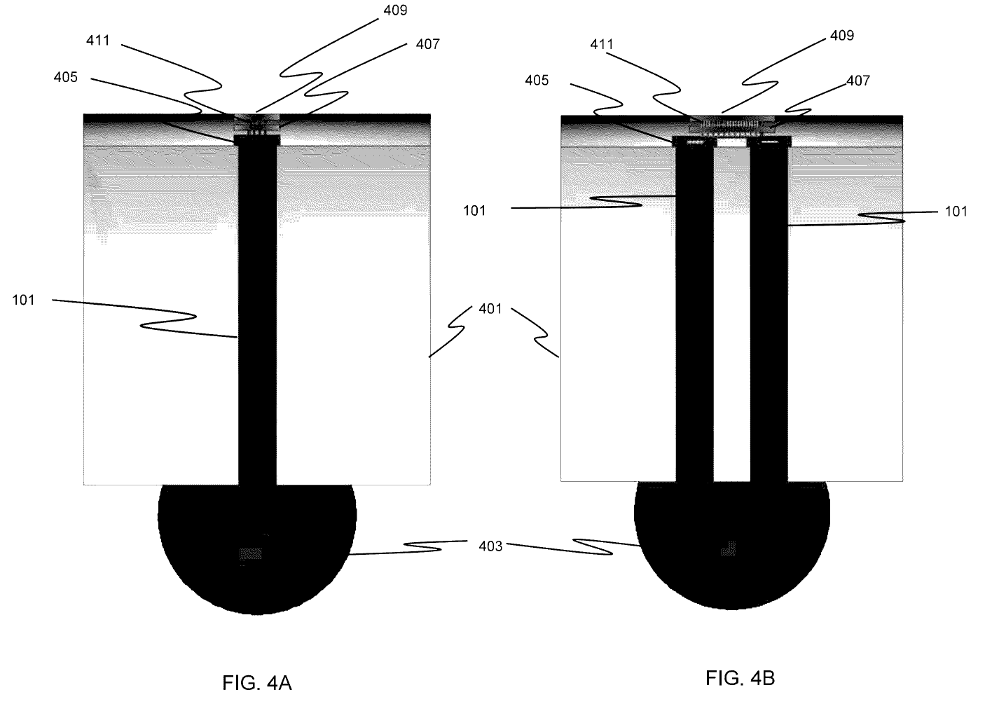

Adverting to FIGS. 4A and 4B, examples of single and double TSV layouts in cross sectional views are illustrated. In FIG. 4A, the single TSV 101 extends through substrate 401. The substrate thickness from a top surface to a backside surface of the substrate 401 in this example is 50 μm. The backside side of the substrate 401 includes an under-bump metallurgy (UBM) pad 403 with solder. The UBM pad 403 is connected with the TSV 101. On the top side of the substrate 401 are the metallization layers 405, 407, 409 stacked on each other with intermetal vias 411 re included between each adjacent pair of the metallization layers 405, 407, 409.

In FIG. 4B, the two TSVs 101 extend through substrate 401. The substrate thickness from a top surface to a backside surface of the substrate 401 in this example is 50 μm. The backside side of the substrate 401 includes an under-bump metallurgy (UBM) pad 403 with solder. The UBM pad 403 is connected with both TSVs 101. On the top side of the substrate 401 are the metallization layers 405 over each respective TSV 101 and which merge with metallization layers 407, 409 stacked over and between the TSVs. Intermetal vias 411 are included between each adjacent pair of the metallization layers 405, 407, 409.

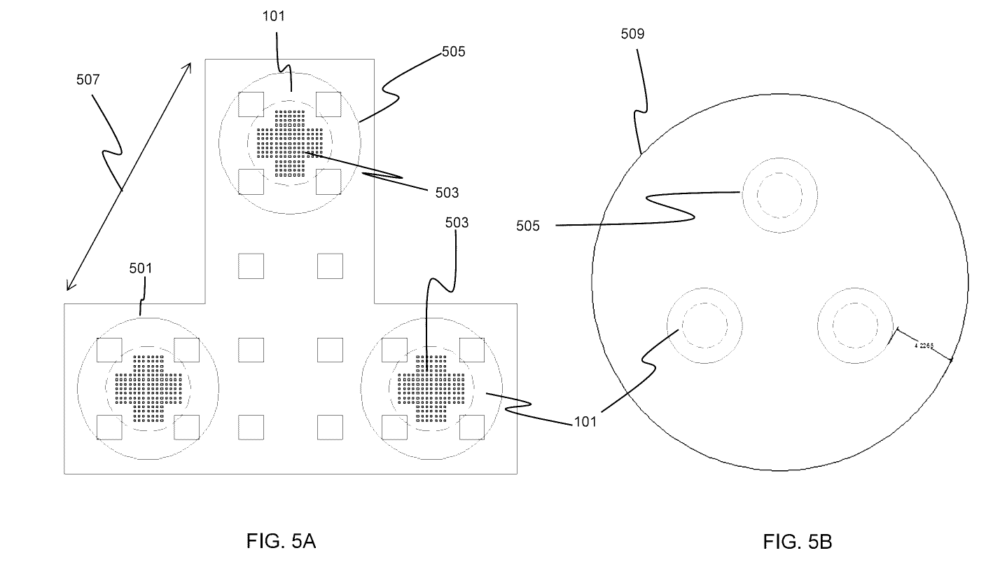

FIGS. 5A and 5B schematically illustrate top and bottom views, respectively, of a triple TSV layout, in accordance with another example. In FIG. 5A only the bottom metal layer through the merging layer is illustrated for simplicity, and the metal layers are omitted. In this example a 10 μm TSV pitch 507 is provided. Intermetal vias 503 are shown in each of the TSVs 101. The outer boundary of each power supply TSV 101 is indicated by a circle 505. FIG. 5B illustrates a bottom view with an outer boundary of the UBM pad shown as circle 509. Each of the three TSVs 101 is included with the outer boundary of the UBM pad. In this example the multiple redundant TSV connections can be used for high power applications and add a safety margin for additional current load. For scenarios where more interconnect redundancy is desired, additional TSV's can be used in a multi-TSV structure. The effect is additional spreading of current over a larger area for reduced maximum current density. A maximum number of redundant TSV's is defined by TSV diameter and diameter of backside capture pad which must remain within dimensional design rules.

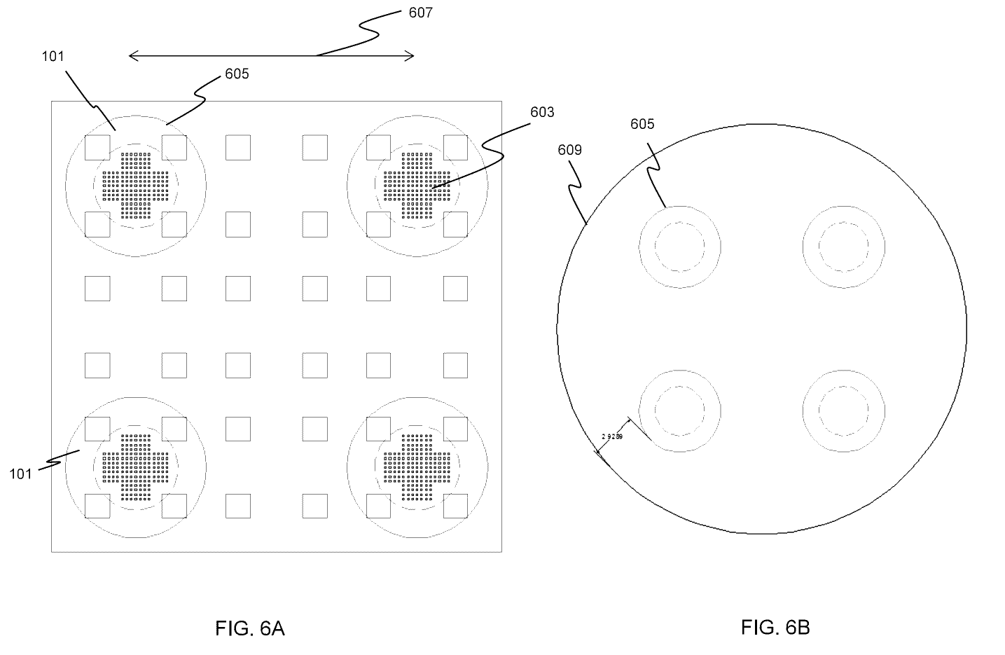

FIGS. 6A and 6B schematically illustrate top and bottom views, respectively, of a quadruple TSV layout. In FIG. 6A only the bottom metal layer through the merging layer is illustrated for simplicity and the metal layers are omitted. In this example a 10 μm TSV pitch 607 is provided. Intermetal vias 603 are shown in each of the TSVs 101. The outer boundary of each power supply TSV 101 is indicated by a circle 605. FIG. 6B illustrates a bottom view with an outer boundary of the UBM pad shown as circle 609. Each of the three TSVs 101 is included with the outer boundary of the UBM pad. In this example the multiple redundant TSV connections can be used for high power applications and add a safety margin for additional current load. For scenarios where more interconnect redundancy is desired, additional TSV's can be used in a multi-TSV structure. The effect is additional spreading of current over a larger area for reduced maximum current density. A maximum number of redundant TSV's is defined by TSV diameter and diameter of backside capture pad, which must remain within dimensional design rules.

The embodiments of the present disclosure can achieve several technical effects, such as providing TSV to BEOL integration structures in high current devices that provide sufficient power directly to a stacked (upper) die without the risk of electromigration failures in the BEOL stack. Further technical effects include reliability redundancy, lower current density in the BEOL stack, and more streamlined power delivery to the top die. Devices formed in accordance with embodiments of the present disclosure enjoy utility in various industrial applications, e.g., microprocessors, smart phones, mobile phones, cellular handsets, set-top boxes, DVD recorders and players, automotive navigation, printers and peripherals, networking and telecom equipment, gaming systems, and digital cameras. The present disclosure therefore enjoys industrial applicability in the manufacture of any of various types of highly integrated semiconductor devices by way of TSV to BEOL integration structures, particularly for the 14 nm technology node and beyond.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
providing a bottom die of a three-dimensional (3D) integrated circuit (IC) stack, the bottom die having a connection pad;
providing a top die of the 3D IC stack, the top die including a plurality of metallization layers having a plurality of intermetal vias provided between the plurality of metallization layers;
forming a back end of line (BEOL) connection structure between the bottom and top dies, the BEOL connection structure having a plurality of power supply through-silicon-vias (TSVs); and
connecting the connection pad electrically to the intermetal vias through the power supply TSVs.

2. The method according to claim 1, further comprising:
filling the power supply TSVs with tungsten or copper.

3. The method according to claim 2, further comprising:
providing the power supply TSVs which extend through a silicon containing substrate.

4. The method according to claim 1, further comprising:
providing a first set of lower metallization layers over a first TSV;
providing a second set of lower metallization layers over a second TSV adjacent to the first TSV; and
converging upper metallization layers of the first and second TSV such that the upper metallization layers are disposed over a portion of both the first and second TSVs,
wherein the upper metallization layers are thicker than the lower metallization layers.

5. The method according to claim 4, further comprising:
providing a third set of lower metallization layers over a third TSV,
wherein the upper metallization layers are shared between the first, second, and third TSVs.

6. The method according to claim 5, further comprising:
providing a fourth set of lower metallization layers over a fourth TSV,
wherein the upper metallization layers are shared between the first, second, third, and fourth TSVs.

7. The method according to claim 6, wherein electrical current is spread among the first, second, third, and fourth TSVs.

8. The method according to claim 1, wherein the connection pad comprises a backside under bump metallization and solder.

9. The method according to claim 1, further comprising:
providing an inter-layer dielectric (ILD) between each of the metallization layers.

10. The method according to claim 1, wherein:
the intermetal vias allow for a direct current flow path; and
a number of intermetal vias between each metallization layer is sufficient to pass current based on a minimum current layer.

11. The method according to claim 1, wherein a maximum current per TSV is determined by a number of intermetal vias present in an upper metallization layer.

12. A device comprising:
a bottom die of a three-dimensional (3D) integrated circuit (IC) stack, the bottom die having a connection pad;
a top die of the 3D IC stack, the top die having a plurality of metallization layers including a plurality of intermetal vias provided between the plurality of metallization layers; and
a back end of line (BEOL) connection structure between the bottom and top dies, the BEOL connection structure having a plurality of power supply through-silicon-vias (TSVs),
wherein the connection pad is electrically connected to the intermetal vias through the power supply TSVs.

13. The device according to claim 12, wherein the TSVs are filled with tungsten or copper.

14. The device according to claim 12, wherein the TSVs extend through a silicon containing substrate.

15. The device according to claim 12, further comprising:
a first set of lower metallization layers are provided over a first TSV;
a second set of lower metallization layers are provided over a second TSV adjacent to the first TSV,
wherein upper metallization layers of the first and second TSV are converged such that the upper metallization layers are disposed over a portion of both the first and second TSVs.

16. The device according to claim 15, wherein:
a third set of lower metallization layers are provided over a third TSV; and
a fourth set of lower metallization layers are provided over a fourth TSV,
wherein the upper metallization layers are converged and shared between the first, second, third and fourth TSVs.

17. A method comprising:
providing a bottom die of a three-dimensional (3D) integrated circuit (IC) stack, the bottom die having a connection pad, the connection pad comprising a backside under bump metallization and solder;
providing a top die of the 3D IC stack, the top die including a plurality of metallization layers having a plurality of intermetal vias provided between the plurality of metallization layers;
forming a back end of line (BEOL) connection structure between the bottom and top dies, the BEOL connection structure having a plurality of power supply through-silicon-vias (TSVs) filled with copper or tungsten;
providing a first set of lower metallization layers over a first TSV;
providing a second set of lower metallization layers over a second TSV adjacent to the first TSV;
converging upper metallization layers of the first and second TSV such that the upper metallization layers are disposed over a portion of both the first and second TSV; and
connecting the connection pad electrically to the intermetal vias through the power supply TSVs.

18. The method according to claim 17, comprising:
providing an inter-layer dielectric (ILD) between each of the metallization layers.

19. The method according to claim 17, further comprising:
providing a third set of lower metallization layers over a third TSV,
wherein the upper metallization layers are converged and shared between the first, second and third TSVs.

20. The method according to claim 19, further comprising:
providing a fourth set of lower metallization layers over a fourth TSV,
wherein the upper metallization layers are converged and shared between the first, second, third and fourth TSVs.
